(19) United States
(12) Patent Application Publication
(10) Pub. No.: US 2024/0120351 A1
(43) Pub. Date: Apr. 11, 2024

(54) IMAGE SENSORS

(71) Applicant: Samsung Electronics Co., Ltd., Suwon-si (KR)

(72) Inventors: Youngrae Kim, Suwon-si (KR); Sanghyuck Moon, Suwon-si (KR); Jueun Park, Suwon-si (KR); Jaeho Lee, Suwon-si (KR); Jeongjin Cho, Suwon-si (KR)

(21) Appl. No.: 18/302,828

(22) Filed: Apr. 19, 2023

(30) Foreign Application Priority Data
Oct. 5, 2022 (KR) 10-2022-0126867

(51) Int. Cl. H01L 27/146

(52) U.S. Cl. CPC H01L 27/14603; H01L 27/14612; H01L 27/14621; H01L 27/14627; H01L 27/1463

(57) ABSTRACT

An image sensor includes a substrate and a pixel separation portion disposed in the substrate and separating first pixels and second pixels from each other. The first pixels and the second pixels are alternately arranged in a first direction and a second direction which intersect each other. Each of the first pixels has a first width in the first direction. Each of the second pixels has a second width in the first direction, which is narrower than the first width. The pixel separation portion includes a main separation portion between the first and second pixels, and protrusions, each of which protrudes from a side surface of the main separation portion in at least one of the first and second directions. Ones of the protrusions protrude into a respective one of the first pixels to divide the respective one of the first pixels into a plurality of sub-pixels.

### CROSS-REFERENCE TO RELATED APPLICATION

This U.S. non-provisional patent application claims priority under 35 U.S.C. § 119 to Korean Patent Application No. 10-2022-0126867, filed on Oct. 5, 2022, in the Korean Intellectual Property Office, the entire contents of which are hereby incorporated by reference.

### BACKGROUND OF THE INVENTION

The present disclosure relates to an image sensor.

An image sensor is a semiconductor device for converting an optical image into electrical signals. Image sensors may be categorized as one of charge coupled device (CCD) image sensors and complementary metal-oxide-semiconductor (CMOS) image sensors. CIS is short for the CMOS image sensor. The CIS may include a plurality of pixels two-dimensionally arranged. Each of the pixels may include a photodiode (PD). The photodiode may convert incident light into an electrical signal.

### SUMMARY

Embodiments of the inventive concepts may provide a highly integrated image sensor capable of realizing clear image quality.

According to some embodiments, an image sensor may include a substrate having a first surface and a second surface opposite to the first surface; and a pixel separation portion disposed in the substrate and separating first pixels and second pixels from each other. The first pixels and the second pixels are alternately arranged in a first direction and a second direction which intersect each other. Each of the first pixels may have a first width in the first direction. Each of the second pixels may have a second width in the first direction, which is less than the first width. The pixel separation portion may include: a main separation portion between the first and second pixels; and protrusions, each of which protrudes from a side surface of the main separation portion in at least one of the first and second directions. Ones of the protrusions protrude into a respective one of the first pixels to divide the respective one of the first pixels into a plurality of sub-pixels.

According to some embodiments, an image sensor may include a substrate having a first surface and a second surface opposite to the first surface; a pixel separation portion disposed in the substrate and separating first pixels and second pixels from each other, which are alternately arranged in first and second directions intersecting each other, the pixel separation portion dividing each of the first pixels into a plurality of sub-pixels, wherein each of the first pixels has a first width in the first direction, and each of the second pixels has a second width in the first direction which is less than the first width: a first photoelectric conversion portion disposed in the substrate in each of the sub-pixels; a first floating diffusion region adjacent to the first surface of the substrate and disposed in the substrate in each of the sub-pixels; a sub-transfer gate disposed at a side of the first floating diffusion region in each of the sub-pixels: a second photoelectric conversion portion disposed in the substrate in each of the second pixels; a second floating diffusion region adjacent to the first surface of the substrate and disposed in the substrate in each of the second pixels; and a second transfer gate disposed at a side of the second floating diffusion region in each of the second pixels.

According to some embodiments, an image sensor may include a substrate having a first surface and a second surface opposite to the first surface; a pixel separation portion disposed in the substrate and separating first pixels and second pixels from each other, which are alternately arranged in first and second directions intersecting each other. wherein each of the first pixels has a first width in the first direction and each of the second pixels has a second width in the first direction which is less than the first width; a first micro lens which is disposed on the second surface of the substrate, is on (e.g., covers) a first one of the first pixels and has a third width: a second micro lens which is disposed on the second surface of the substrate, is on (e.g., covers) a second one of the first pixels and has a fourth width: a third micro lens which is disposed on the second surface of the substrate, is on (e.g., covers) the second pixel and has a fifth width. a first color filter disposed between the second surface of the substrate and the first micro lens; and a second color filter disposed between the second surface of the substrate and the second micro lens. A color filter may not exist between the third micro lens and the second surface. The fourth width may be less than the third width and may be greater than the fifth width. The first color filter may have a blue color, and the second color filter may have one of a green color and a red color. In some embodiments, a space between the third micro lens and the second surface of the substrate is free of a color filter.

### BRIEF DESCRIPTION OF THE DRAWINGS

FIG. 1 is a plan view illustrating an image sensor according to some embodiments of the inventive concepts.

FIG. 2 is an enlarged view of a portion ‘P1’ of FIG. 1 to illustrate an image sensor according to some embodiments of the inventive concepts.

FIG. 3 is a cross-sectional view taken along a line A-A′ of FIG. 2 to illustrate an image sensor according to some embodiments of the inventive concepts.

FIGS. 4A and 4B are each cross-sectional views taken along a line B-B′ of FIG. 2 to illustrate image sensors according to some embodiments of the inventive concepts.

FIG. 5 is a cross-sectional view illustrating an image sensor according to some embodiments of the inventive concepts.

FIG. 6 is a plan view illustrating an image sensor according to some embodiments of the inventive concepts.

FIG. 7 is a circuit diagram of the image sensor of FIG. 6.

FIG. 8 is a cross-sectional view illustrating an image sensor according to some embodiments of the inventive concepts

FIG. 9 is a cross-sectional view illustrating an image sensor according to some embodiments of the inventive concepts.

FIG. 10 is an enlarged view of the portion T1′ of FIG. 1 to illustrate an image sensor according to some embodiments of the inventive concepts.

FIG. 11 is a plan view illustrating an image sensor according to some embodiments of the inventive concepts.

FIG. 12 is a circuit diagram of the image sensor of FIG. 11.

FIG. 13 is a plan view illustrating an image sensor according to some embodiments of the inventive concepts.

FIG. 14 is a cross-sectional view taken along lines C-C′ and D-D′ of FIG. 13.

FIG. 15 is a cross-sectional view illustrating an image sensor according to some embodiments of the inventive concepts.

FIG. 16 is a cross-sectional view illustrating an image sensor according to some embodiments of the inventive concepts.

### DETAILED DESCRIPTION

Example embodiments of the inventive concepts will now be described more fully with reference to the accompanying drawings.

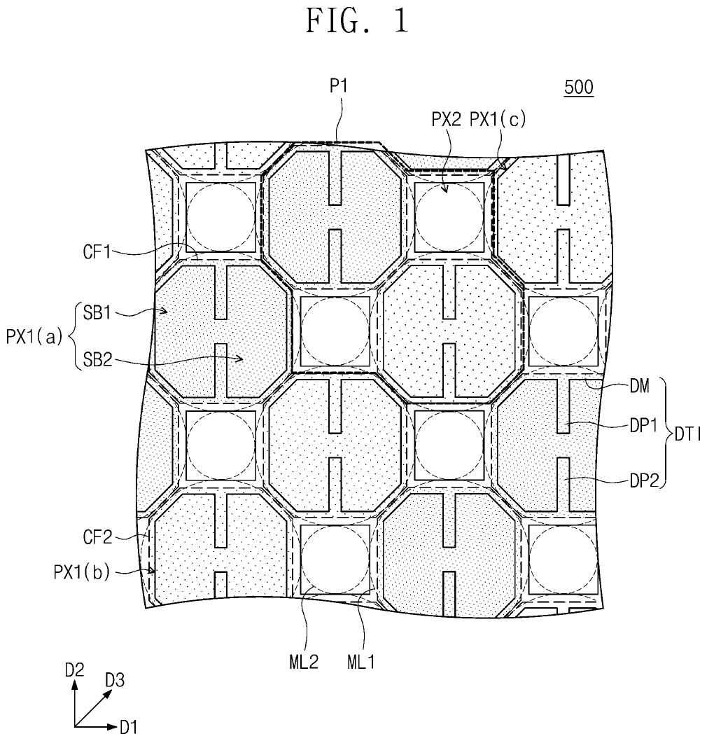

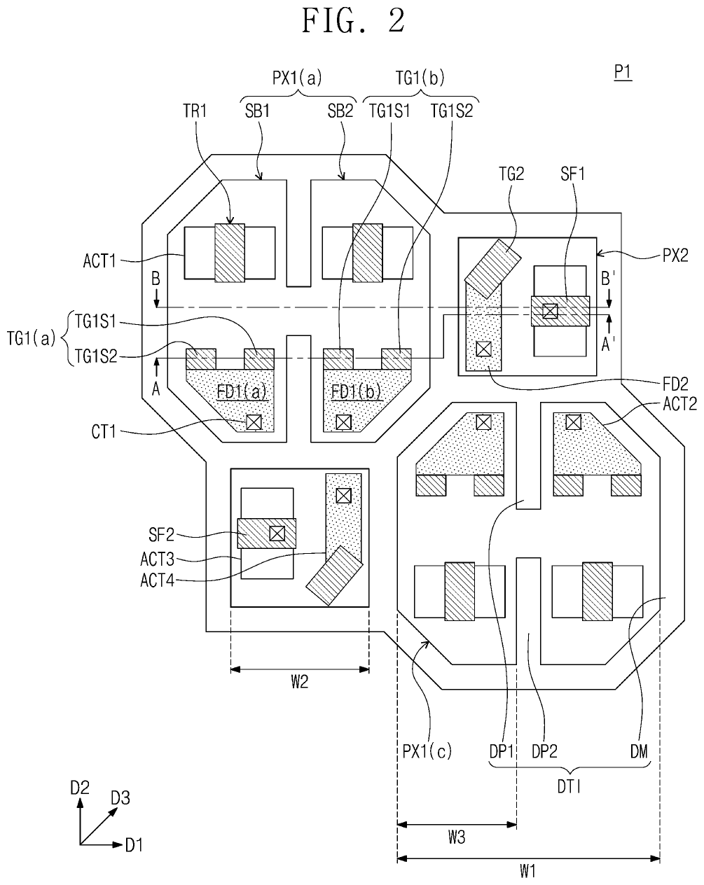

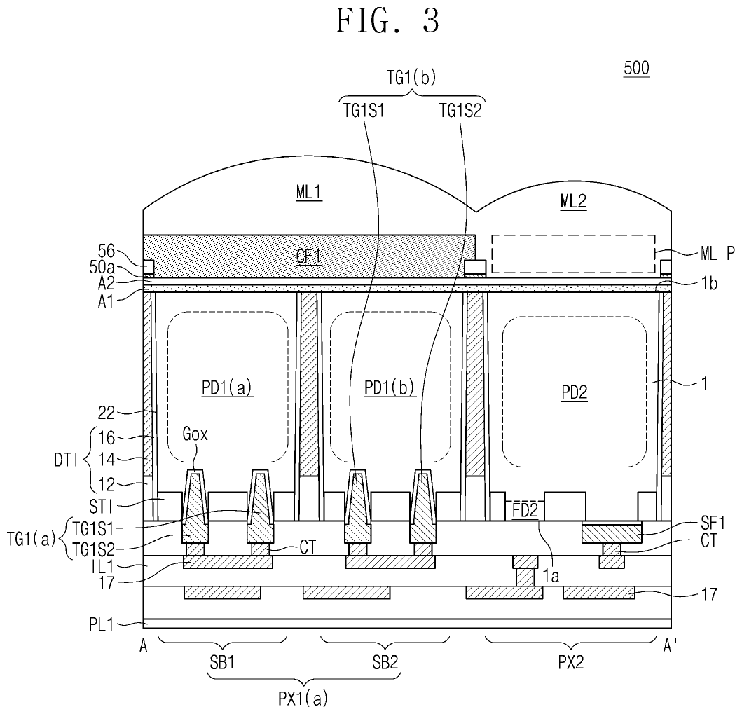

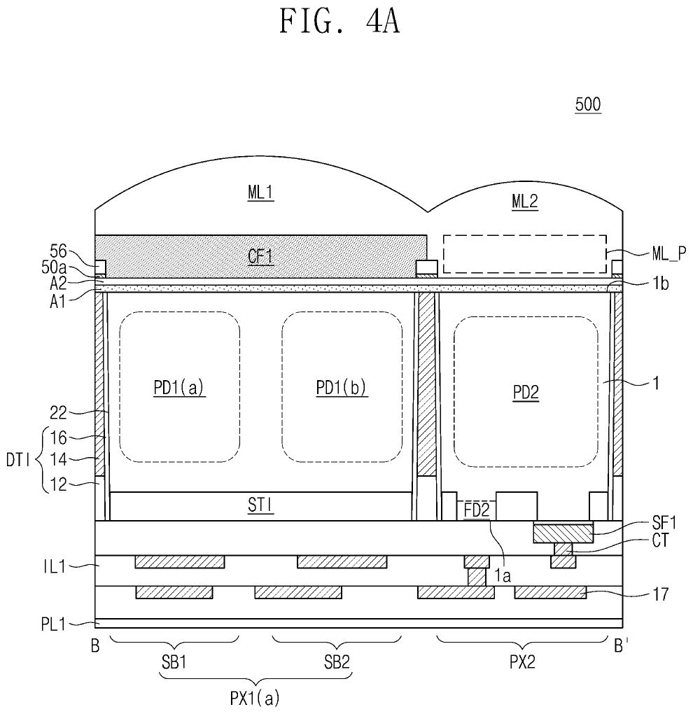

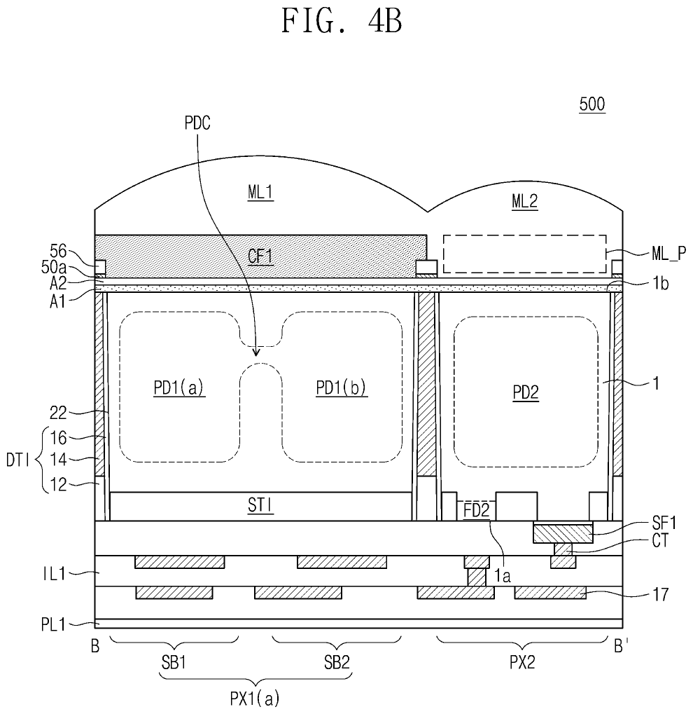

FIG. 1 is a plan view illustrating an image sensor according to some embodiments of the inventive concepts. FIG. 2 is an enlarged view of a portion P1′ of FIG. 1 to illustrate an image sensor according to some embodiments of the inventive concepts. FIG. 3 is a cross-sectional view taken along a line A-A of FIG. 2 to illustrate an image sensor according to some embodiments of the inventive concepts. FIGS. 4A and 4B are each cross-sectional views taken along a line B-B′ of FIG. 2 to illustrate image sensors according to some embodiments of the inventive concepts.

Referring to FIGS. 1, 2, 3, 4A and 4B, an image sensor 500 according to some embodiments of the inventive concepts may include a first substrate 1. For example, the first substrate 1 may be a single-crystalline silicon wafer, a silicon epitaxial layer, or a silicon-on-insulator (SOI) substrate. For example, the first substrate 1 may be doped with dopants having a first conductivity type. For example, the first conductivity type may be a P-type. The first substrate 1 may include a front surface 1a and a back surface 1b which are opposite to each other. In the present specification, the front surface 1a may be referred to as a first surface 1a, and the back surface 1b may be referred to as a second surface 1b.

A pixel separation portion DTI may be disposed in the first substrate 1 to isolate a plurality of first pixels PX1 and a plurality of second pixels PX2 from each other. The first pixels PX1 and the second pixels PX2 may be two-dimensionally arranged in a first direction D1 and a second direction D2 and may be alternately arranged in each of the first and second directions D1 and D2. Each of the first pixels PX1 may have an octagonal shape when viewed in a plan view. In particular, each of the first pixels PX1 may have a regular octagonal shape in a plan view and may have eight side surfaces having the same length/width. Each of the second pixels PX2 may have a tetragonal shape when viewed in a plan view. In particular, each of the second pixels PX2 may have a regular tetragonal shape (or a square shape) in a plan view and may have four side surfaces having the same length/width. Each of the first pixels PX1 may have a first width W1 in the first direction D1. Each of the second pixels PX2 may have a second width W2 in the first direction D1, which is less than the first width W1. In particular, the first width W1 may be (1+√2) times the second width W2.

The first pixels PX1 may be colored color pixels for realizing an image. The first pixels PX1 may include first color pixels PX1(a), second color pixels PX1(b), and third color pixels PX1(c). First color filters CF1 may be disposed on the first color pixels PX1(a), respectively. Second color filters CF2 may be disposed on the second color pixels PX1(b), respectively. Third color filters CF3 may be disposed on the third color pixels PX1(c), respectively.

Each of the first, second and third color filters CF1, CF2 and CF3 (also referred to as the color filters CF1, CF2 and CF3) may have one of a blue color, a green color, and a red color. In some embodiments, each of the color filters CF1, CF2 and CF3 may have another color such as a cyan color, a magenta color, or a yellow color. The color filters CF1, CF2 and CF3 may be arranged in a Bayer pattern form. In some embodiments, the color filters CF1, CF2 and CF3 may be arranged in a 2×2 Tetra pattern form, a 3×3 Nona pattern form or a 4×4 hexadeca pattern form. In some embodiments, the color filters CF1, CF2 and CF3 may be arranged in a Kodak pattern form or a Canon pattern form.

The second pixels PX2 may be white pixels for improving sensitivity or brightness. A white filter (or a colorless transparent filter) may be disposed on the second pixel PX2, or a portion of a micro lens or the same material as the micro lens may be provided on the second pixel PX2.

The pixel separation portion DTI may include a main separation portion DM disposed between the first pixels PX1 and the second pixels PX2 in a plan view, and protrusions DP1 and DP2 protruding from a side surface of the main separation portion DM into the first pixels PX1 in a plan view, as shown in FIGS. 1 and 2. The protrusions DP1 and DP2 of the pixel separation portion DTI may divide each of the first pixels PX1 into a first left sub-pixel SB1 and a first right sub-pixel SB2. Each of the first left sub-pixel SB1 and the first right sub-pixel SB2 may have a third width W3 in the first direction D1. The third width W3 may be less than the first width W1. The third width W3 may be less than the second width W2.

The protrusions DP1 and DP2 may have a first protrusion DP1 and a second protrusion DP2. The first protrusion DP1 may extend in a direction opposite to the second direction D2. The second protrusion DP2 may extend in the second direction D2. The first protrusion DP1 and the second protrusion DP2 may be aligned with each other in the second direction D2. The first protrusion DP1 and the second protrusion DP2 may not be in contact with each other but may be spaced apart from each other. The first pixels PX1 may provide an auto-focus function. The image sensor 500 may be an auto-focus image sensor. As used herein, “an element A extends in a direction X” (or similar language) may mean that the element A extends longitudinally in the direction X.

The pixel separation portion DTI may be located in a deep trench 22 formed from the front surface 1a of the first substrate 1 toward the back surface 1b of the first substrate 1. The pixel separation portion DTI may have a width becoming narrower from the front surface 1a toward the back surface 1b of the first substrate 1. The pixel separation portion DTI may include a filling insulation pattern 12, an isolation insulating pattern 16, and an isolation conductive pattern 14. The filling insulation pattern 12 may be disposed between the isolation conductive pattern 14 and a first interlayer insulating layer ILL The isolation insulating pattern 16 may be disposed between the isolation conductive pattern 14 and the first substrate 1 and between the filling insulation pattern 12 and the first substrate 1. Like the pixel separation portion DTI, the isolation conductive pattern 14 may have a mesh shape when viewed in a plan view. A negative bias may be applied to the isolation conductive pattern 14. The isolation conductive pattern 14 may function as a common bias line. Thus, a dark current and/or a white spot of the image sensor 500 may be reduced or minimized.

Each of the filling insulation pattern 12 and the isolation insulating pattern 16 may be formed of an insulating material having a refractive index different from that of the first substrate 1. For example, the filling insulation pattern 12 and the isolation insulating pattern 16 may include silicon oxide. The isolation conductive pattern 14 may be spaced apart from the first substrate 1. The isolation conductive pattern 14 may include a poly-silicon layer or silicon-germanium layer, which is doped with dopants. For example, the dopants doped in the poly-silicon layer or silicon-germanium layer may be boron, phosphorus, or arsenic. In some embodiments, the isolation conductive pattern 14 may include a metal layer.

First photoelectric conversion portions PD1 may be disposed in the first substrate 1 in the first left and right sub-pixels SB1 and SB2 of each of the first pixels PX1, respectively. The first photoelectric conversion portions PD1 may include a first left photoelectric conversion portion PD1(a) disposed in the first left sub-pixel SB1, and a first right photoelectric conversion portion PD1(b) disposed in the first right sub-pixel SB2. Second photoelectric conversion portions PD2 may be disposed in the first substrate 1 of the second pixels PX2, respectively. The photoelectric conversion portions PD1 and PD2 may be doped with dopants having a second conductivity type opposite to the first conductivity type. For example, the second conductivity type may be an N-type. The N-type dopants doped in the photoelectric conversion portions PD1 and PD2 may form PN junctions with the P-type dopants doped in the first substrate 1 therearound to provide photodiodes. The first left photoelectric conversion portion PD1(a) and the first right photoelectric conversion portion PD1(b) may be spaced apart from each other, as illustrated in FIG. 4A. In some embodiments, portions PDC of the first left photoelectric conversion portion PD1(a) and the first right photoelectric conversion portion PD1(b) may be connected to each other, as illustrated in FIG. 4B. Thus, linearity of an electrical signal generated in the left and right sub-pixels SB1 and SB2 may be enhanced to improve the auto-focus function.

Device isolation portions STI adjacent to the front surface 1a may be disposed in the first substrate 1. For example, each of the device isolation portions STI may have a single-layered or multi-layered structure including at least one of silicon oxide, silicon nitride, or silicon oxynitride. The pixel separation portion DTI may penetrate the device isolation portions STI. The device isolation portions STI may define first to fourth active regions ACT1 to ACT4 adjacent to the front surface 1a in the pixels PX1 and PX2.

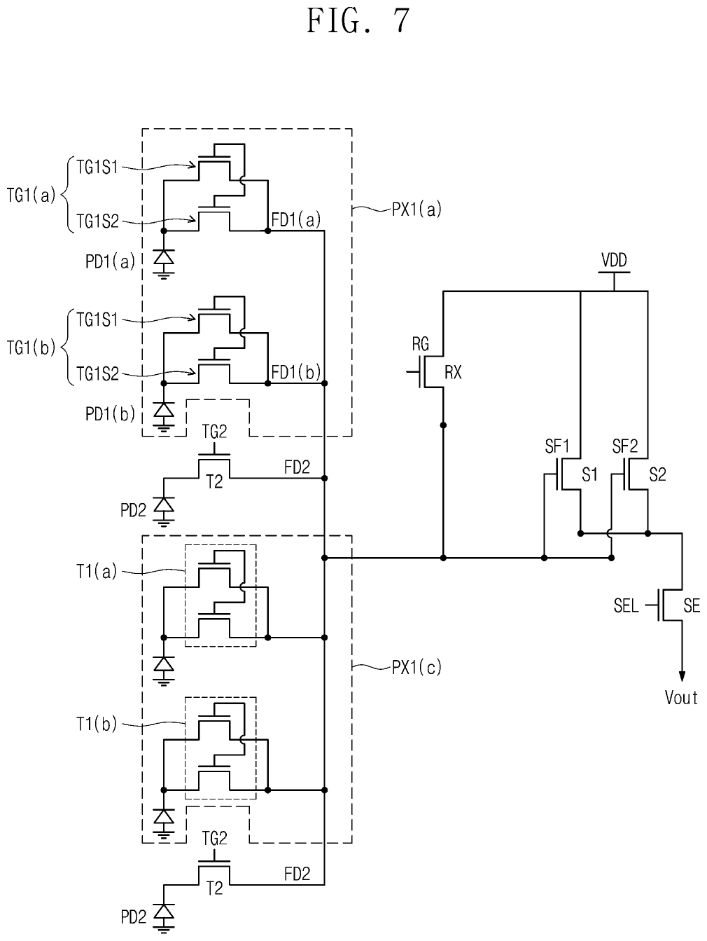

The first to fourth active regions ACT1 to ACT4 may be provided for transistors T1, T2, RX, S1, S2 and SE of FIG. 7. The first active regions ACT1 may be provided for first transistors TR1 and may be disposed in the first left and right sub-pixels SB1 and SB2 of the first pixel PX1. Each of the first transistors TR1 may correspond to one of a reset transistor RX and a selection transistor SE.

The second active regions ACT2 may be provided for first transfer transistors T1 of the first pixel PX1 and may be disposed in the first left and right sub-pixels SB1 and SB2 of the first pixel PX1. Each of the first transfer transistors T1 may include a first transfer gate TG1 and a first floating diffusion region FD1 disposed adjacent to (e.g., at) a side of the first transfer gate TG1. In some embodiments, the first floating diffusion region FD1 may be adjacent to (e.g., at) a side of the first transfer gate TG1 in a plan view, as illustrated in FIG. 2. The first transfer transistors T1 may include a first left transfer transistor T1(a) disposed in the first left sub-pixel SB1, and a first right transfer transistor T1(b) disposed in the first right sub-pixel SB2.

The first left transfer transistor T1(a) may include a first left transfer gate TG1(a) and a first left floating diffusion region FD1(a). The first right transfer transistor T1(b) may include a first right transfer gate TG1(b) and a first right floating diffusion region FD1(b). Each of the first left transfer gate TG1(a) and the first right transfer gate TG1(b) may include a plurality of sub-transfer gates TG1S1 and TG1S2. In other words, the sub-transfer gates TG1S1 and TG1S2 may include a first sub-transfer gate TG1S1 and a second sub-transfer gate TG1S2. Thus, the first left transfer transistor T1(a) and the first right transfer transistor T1(b) may operate as two transistors connected in parallel to each other, respectively, as illustrated in FIG. 7. As a result, the first left transfer transistor T1(a) and the first right transfer transistor T1(b) may be operated by lower driving voltages.

The number of the sub-transfer gates TG1S1 and TG1S2 is not limited to two and may be three or more. In some embodiments, each of the first left transfer gate TG1(a) and the first right transfer gate TG1(b) may not be divided into the plurality of sub-transfer gates but may be a single transfer gate.

In each of the first left transfer gate TG1(a) and the first right transfer gate TG1(b), the first sub-transfer gate TG1S1 and the second sub-transfer gate TG1S2 may be connected to each other through an interconnection line 17. The first sub-transfer gate TG1S1 and the second sub-transfer gate TG1S2 adjacent to each other may be spaced apart from each other in the first direction D1.

Portions of the first sub-transfer gate TG1S1 and the second sub-transfer gate TG1S2 may extend into the first substrate 1. The first sub-transfer gate TG1S1 and the second sub-transfer gate TG1S2 may be vertical-type gates. In some embodiments, the first sub-transfer gate TG1S1 and the second sub-transfer gate TG1S2 may not extend into the first substrate 1 and may be planar-type gates having flat shapes. A gate insulating layer Gox may be disposed between the first substrate 1 and the first and second sub-transfer gates TG1S1 and TG1S2. The gate insulating layer Gox may include silicon oxide.

The third active regions ACT5 may be provided for source follower transistors S1 and S2 and may be disposed in the second pixels PX2. The source follower transistors S1 and S2 may include source follower gates SF1 and SF2, respectively.

The fourth active region ACT4 may be provided for a second transfer transistor T2 and may be disposed in the second pixel PX2. The second transfer transistor T2 may include a second transfer gate TG2 and a second floating diffusion region FD2. Some of side surfaces of the second transfer gate TG2 may be arranged in a third direction D3 which intersects both the first direction D1 and the second direction D2 and is parallel to the first surface 1a of the first substrate 1 when viewed in a plan view. One side surface of the fourth active region ACT4 may intersect one side surface of the second transfer gate TG2.

Planar shapes (layout) of the first transfer transistors T1 may be different from that of the second transfer transistor T2. Thus, a highly integrated image sensor may be realized.

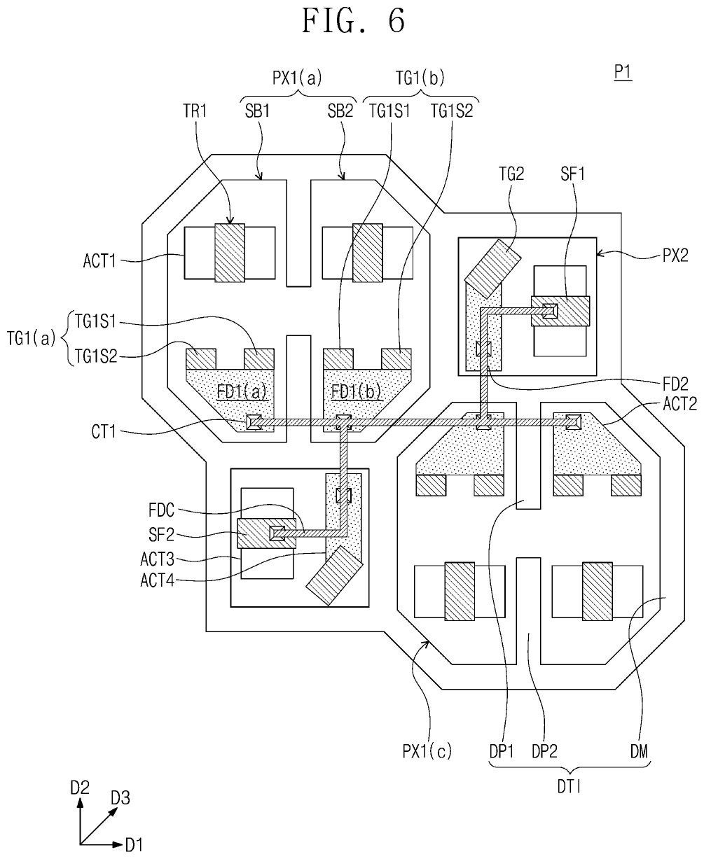

The front surface 1a of the first substrate 1 may be covered with a plurality of stacked interlayer insulating layers IL1. Each of the interlayer insulating layers IL1 may have a single-layered or multi-layered structure including at least one of silicon oxide, silicon nitride, silicon oxynitride, or a porous insulating layer. Contacts CT, interconnection lines 17 and a floating diffusion region connection line FDC of FIG. 6 may be disposed in the interlayer insulating layers ILL A lowermost interlayer insulating layer IL1 may be covered with a passivation layer PL1. For example, the passivation layer PL1 may have a single-layered or multi-layered structure including at least one of silicon oxide, silicon nitride, or SiCN.

A fixed charge layer A1 and an anti-reflection layer A2 may sequentially cover the back surface 1b of the first substrate 1. The fixed charge layer A1 may be in contact with the back surface 1b. The fixed charge layer A1 may have negative fixed charges. The fixed charge layer A1 may be formed of a metal oxide or metal fluoride including at least one metal selected from a group consisting of hafnium (Hf), zirconium (Zr), aluminum (Al), tantalum (Ta), titanium (Ti), yttrium (Y), and a lanthanoid. For example, the fixed charge layer A1 may be a hafnium oxide layer or an aluminum oxide layer. Here, holes may be accumulated in the vicinity of the fixed charge layer A1. Thus, a dark current and a white spot may be effectively reduced.

The anti-reflection layer A2 may have a single-layered or multi-layered structure including at least one of titanium oxide, silicon nitride, silicon oxide, or hafnium oxide.

A light blocking grid 50a may be disposed on the anti-reflection layer A2. The light blocking grid 50a may overlap with the pixel separation portion DTI. For example, the light blocking grid 50a may include at least one of titanium, titanium nitride, or tungsten. A low-refractive index pattern 56 may be disposed on the light blocking grid 50a. The low-refractive index pattern 56 may include a material having a refractive index less than refractive indexes of the color filters CF1, CF2 and CF3. In particular, the low-refractive index pattern 56 may have a refractive index of 1.3 or less. Side surfaces of the light blocking grid 50a may be aligned with side surfaces of the low-refractive index pattern 56. The light blocking grid 50a and the low-refractive index pattern 56 may not exist on the center of the first pixel PX1 (or on a position between the first left and right sub-pixels SB1 and SB2).

One of the color filters CF1, CF2 and CF3 and a first micro lens ML1 may be sequentially stacked on the first pixel PX1. The color filters CF1, CF2 and CF3 may not be disposed on the second pixel PX2, as illustrated in FIG. 3. A second micro lens ML2 may be disposed on the second pixel PX2. An edge of the first micro lens ML1 may be connected to an edge of the second micro lens ML2. A portion ML_P of the second micro lens ML2 may be disposed between the low-refractive index patterns 56 adjacent to each other and may be in contact with the anti-reflection layer A2. In some embodiments, a color filter may not be provided between the back surface 1b of the first substrate 1 and the second micro lens ML2, and thus a space between the back surface 1b of the first substrate 1 and the second micro lens ML2 may be free of a color filter, as illustrated in FIGS. 3, 4A and 4B.

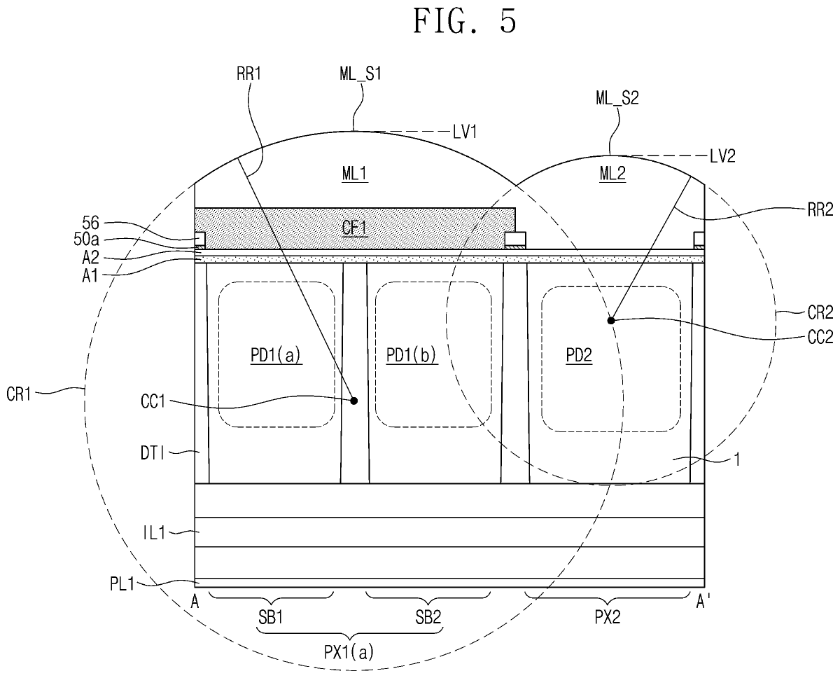

FIG. 5 is a cross-sectional view illustrating an image sensor according to some embodiments of the inventive concepts. For simplicity of illustration, FIG. 5 does not show some elements (e.g., the first and second sub-transfer gates TG1S1 and TG1S2 and the interconnection line 17) shown in FIG. 3.

Referring to FIG. 5, a top surface ML_S1 of the first micro lens ML1 may have a first curvature, and a top surface ML_S2 of the second micro lens ML2 may have a second curvature. The second curvature may be greater than the first curvature. A top end of the first micro lens ML1 may have a first level LV1. A top end of the second micro lens ML2 may have a second level LV2 lower than the first level LV1. Stated differently, an uppermost end of the first micro lens ML1 may be farther than an uppermost end of the second micro lens ML2 from the first substrate 1 (e.g., the back surface 1b of the first substrate 1).

The top surface ML_S1 of the first micro lens ML1 may coincide with an arc of a first imaginary circle CR1 having a first radius RR1 and a first center CC1. The top surface ML_S2 of the second micro lens ML2 may coincide with an arc of a second imaginary circle CR2 having a second radius RR2 and a second center CC2. The first radius RR1 may be greater than the second radius RR2. The first center CC1 may be a focus of the first micro lens ML1. The first center CC1 may be located at the center of the first pixel PX1 when viewed in a plan view. The second center CC2 may be a focus of the second micro lens ML2 and may be located at the center of the second pixel PX2 in a plan view. A focus distance may be adjusted/improved by a curvature difference and a level difference between the first and second micro lenses ML1 and ML2. Thus, an optical property according to light of each wavelength may be easily controlled.

FIG. 6 is a plan view illustrating an image sensor according to some embodiments of the inventive concepts. FIG. 7 is a circuit diagram of the image sensor of FIG. 6.

Referring to FIGS. 6 and 7, the floating diffusion region connection line FDC may connect the first left and right floating diffusion regions FD1(a) and FD1(b) of the first color pixel PX1(a) and the third color pixel PX1(c). In addition, the floating diffusion region connection line FDC may be connected to the second floating diffusion regions FD2 of the second pixels PX2 adjacent to each other in the third direction D3. The floating diffusion region connection line FDC may also be connected to first and second source follower gates SF1 and SF2 disposed in the second pixels PX2 adjacent to each other in the third direction D3.

Referring to FIG. 7, each of the photoelectric conversion portions PD1 and PD2 may generate and accumulate photocharges in proportion to the amount of light incident from the outside. The transfer transistor T1(a), T1(b) or T2 may transfer charges generated from the photoelectric conversion portion PD1 or PD2 to the floating diffusion region FD1 or FD2. The floating diffusion region FD1 or FD2 may receive the charges generated in the photoelectric conversion portion PD1 or PD2 and may cumulatively store the received charges. The source follower transistor S1 or S2 may be controlled depending on the amount of the photocharges accumulated in the floating diffusion region FD1 or FD2.

The reset transistor RX may periodically reset the charges accumulated in the floating diffusion regions FD1 and FD2. A drain electrode of the reset transistor RX may be connected to the floating diffusion regions FD1 and FD2, and a source electrode of the reset transistor RX may be connected to a power voltage VDD. When the reset transistor RX is turned-on, the power voltage VDD connected to the source electrode of the reset transistor RX may be applied to the floating diffusion regions FD1 and FD2. Thus, when the reset transistor RX is turned-on, the charges accumulated in the floating diffusion regions FD1 and FD2 may be discharged to reset the floating diffusion regions FD1 and FD2.

The source follower transistors S1 and S2 including the source follower gate electrodes SF1 and SF2 may function as source follower buffer amplifiers. The source follower transistors S1 and S2 may amplify a potential change in the floating diffusion regions FD1 and FD2 and may output the amplified potential change to an output line Vout.

The selection transistor SE including a selection gate electrode SEL may select the pixels PX1 and PX2 to be sensed in the unit of row. When the selection transistor SE is turned-on, the power voltage VDD may be applied to drain electrodes of the source follower transistors S1 and S2.

The transfer transistors T1(a), T1(b) and T2 may be turned-on at the same time, and thus electrical signals of a group of the pixels PX1 and PX2 may be merged with each other so as to be read as an output value of a single pixel. In some embodiments, the transfer transistors T1(a), T1(b) and T2 included in the group may be sequentially turned-on, and thus an output value of each of the pixels may be read separately.

As a pixel size has been reduced, a size of a designed transistor has also been reduced. However, related pixel performance may be deteriorated due to the reduction in transistor size. The first pixels PX1 and the second pixels PX2 may have different sizes (e.g., widths) and different shapes in the image sensor 500 according to the inventive concepts, and thus a highly integrated image sensor may be realized. The sizes of the first pixels PX1 for realizing an image and performing the auto-focus function may be greater than the sizes of the second pixels PX2 for realizing brightness, thereby reducing (e.g., minimizing) or preventing reduction in size of the transfer transistor, realizing clear image quality, and improving the auto-focus function.

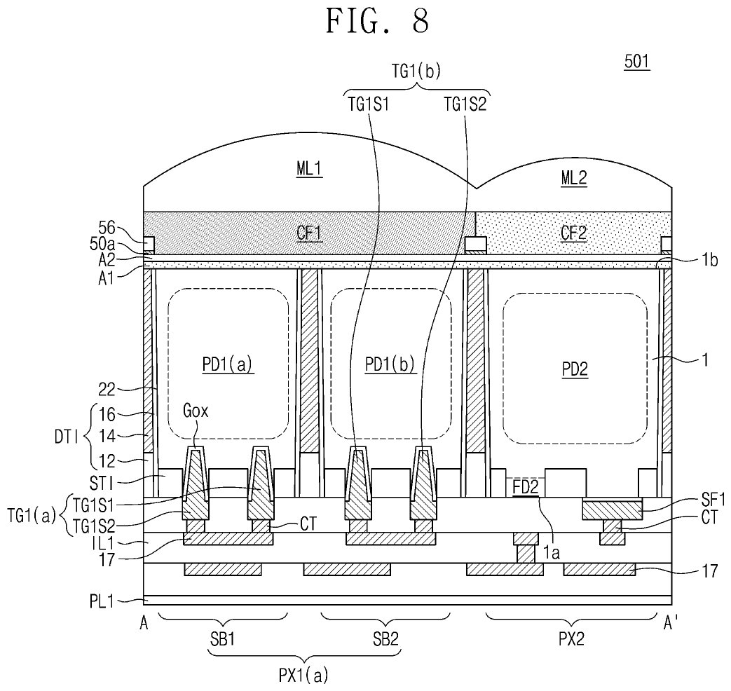

FIG. 8 is a cross-sectional view illustrating an image sensor according to some embodiments of the inventive concepts.

Referring to FIG. 8, in an image sensor 501 according to the present embodiments, a second color filter CF2 may be disposed on the second pixel PX2. The second color filter CF2 may be different from the first color filter CF1 disposed on the first pixel PX1. The second color filter CF2 may be white or colorless and thus may be transparent. Other components may be the same as or similar to those described with reference to FIG. 3.

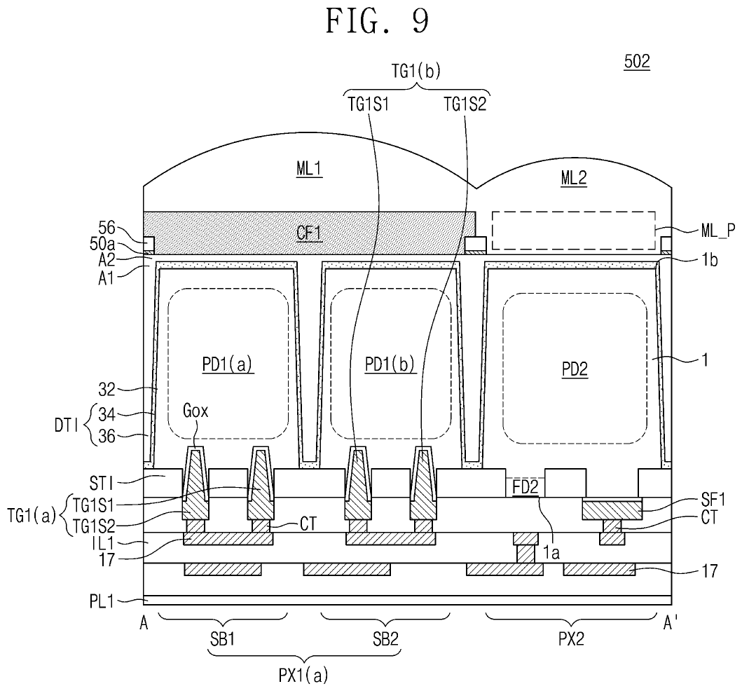

FIG. 9 is a cross-sectional view illustrating an image sensor according to some embodiments of the inventive concepts.

Referring to FIG. 9, in an image sensor 502 according to the present embodiments, a pixel separation portion DTI may be disposed in a deep trench 32 formed from the back surface 1b toward the front surface 1a of the first substrate 1. The pixel separation portion DTI may include a fixed charge layer 34 and a filling insulation layer 36. The fixed charge layer 34 may be in contact with the back surface 1b of the first substrate 1 and may be in contact with an inner surface of the deep trench 32. The fixed charge layer 34 may be in contact with the device isolation portion STI at a bottom of the deep trench 32. The filling insulation layer 36 may fill the deep trench 32 and may cover the back surface 1b of the first substrate 1. The light blocking grid 50a and the color filters CF1, CF2 and CF3 may be disposed on the filling insulation layer 36. A portion ML_P of the second micro lens ML2 may be in contact with the filling insulation layer 36. Other components may be the same as or similar to those described with reference to FIG. 3.

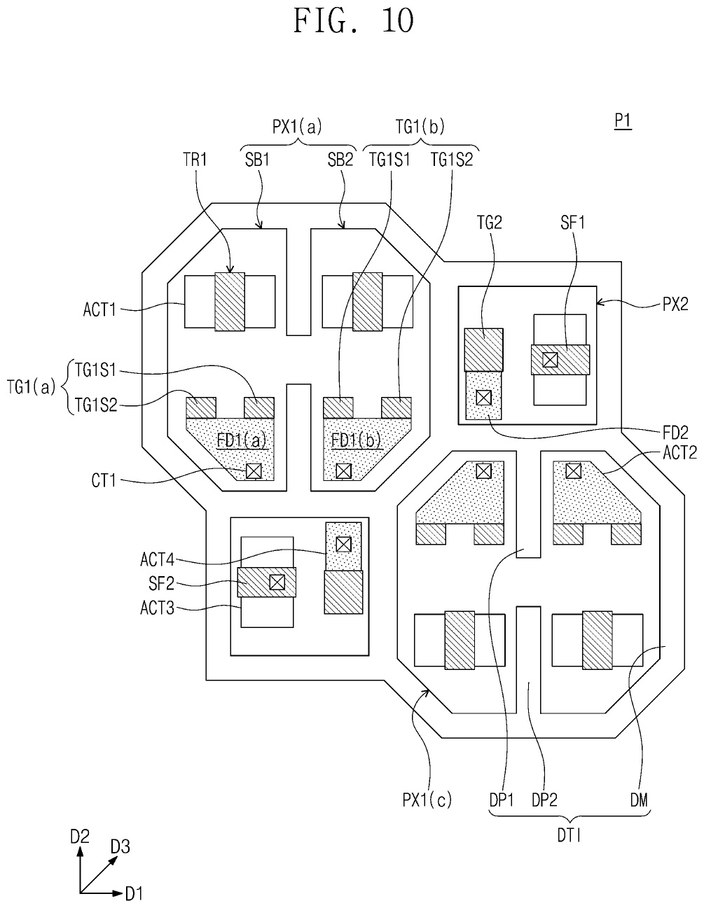

FIG. 10 is an enlarged view of the portion ‘P1’ of FIG. 1 to illustrate an image sensor according to some embodiments of the inventive concepts.

Referring to FIG. 10, in an image sensor according to the present embodiments, some of side surfaces of the second transfer gate TG2 may be parallel to the second direction D2. The some of the side surfaces of the second transfer gate TG2 may be parallel to some of side surfaces of the fourth active region ACT4. Other components may be the same as or similar to those described with reference to FIG. 2.

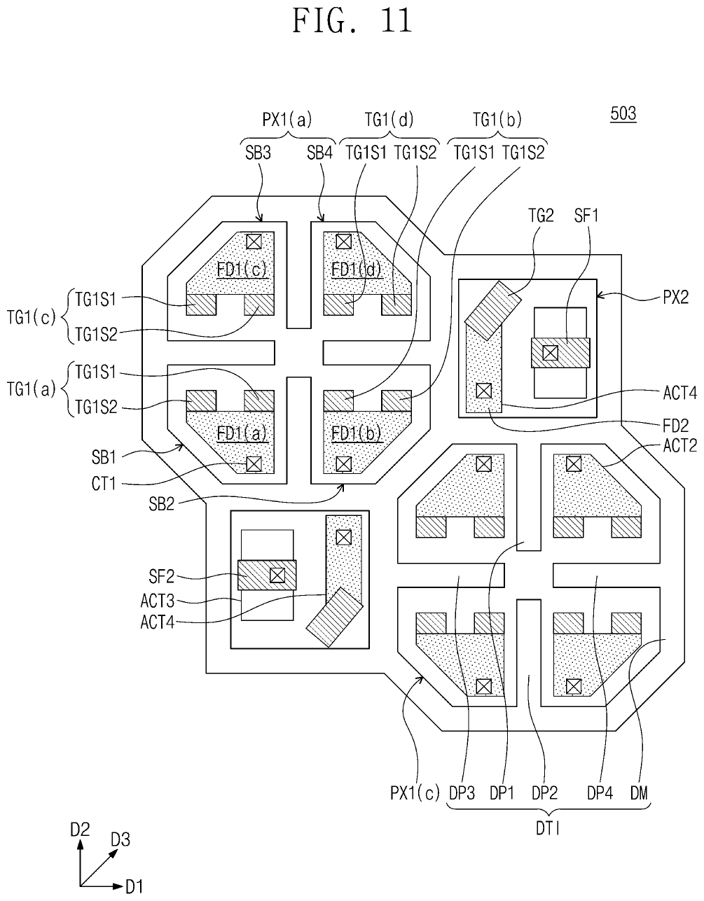

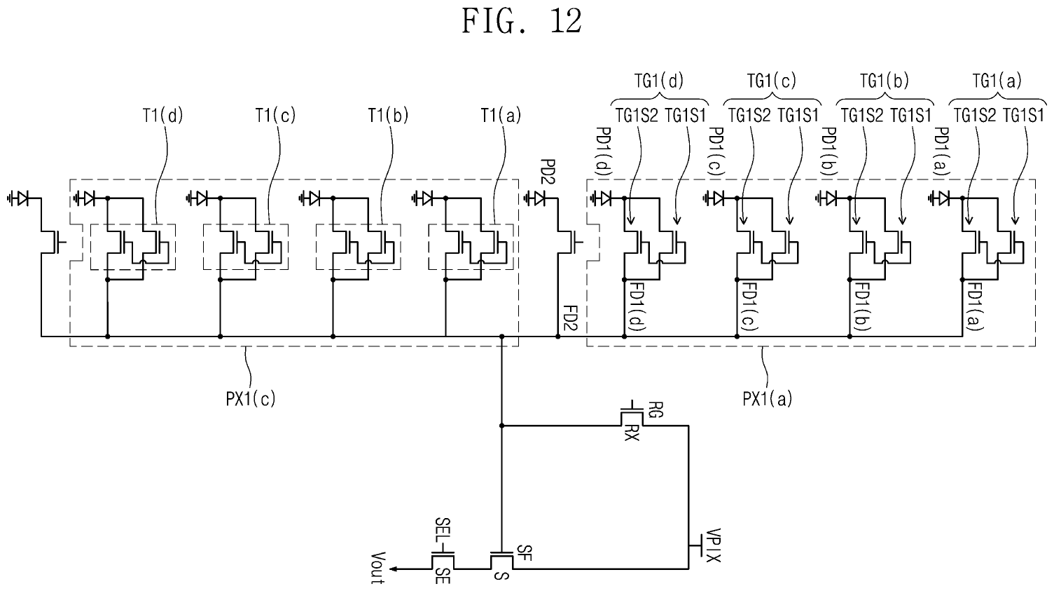

FIG. 11 is a plan view illustrating an image sensor according to some embodiments of the inventive concepts. FIG. 12 is a circuit diagram of the image sensor of FIG. 11.

Referring to FIGS. 11 and 12, in an image sensor 503 according to the present embodiments, a pixel separation portion DTI may divide each of the first pixels PX1 into four sub-pixels SB1 to SB4. The pixel separation portion DTI may have first to fourth protrusions DP1, DP2, DP3 and DP4. The first and second protrusions DP1 and DP2 may be spaced apart from each other in the second direction D2. The third and fourth protrusions DP3 and DP4 may be spaced apart from each other in the first direction D1. At a center portion of the first pixel PX1, the first to fourth protrusions DP1, DP2, DP3 and DP4 may not be in contact with each other but may be spaced apart from each other. The sub-pixels SB1 to SB4 may include first to fourth sub-pixels SB1 to SB4. First transfer transistors T1(a) to T1(d) may be disposed in the sub-pixels SB1 to SB4, respectively. The first transfer transistors T1(a) to T1(d) may include first transfer gates TG1(a) to TG1(d), respectively. Each of the first transfer gates TG1(a) to TG1(d) may include a plurality of sub-transfer gates TG1S1 and TG1S2. Other components may be the same as or similar to those described with reference to FIGS. 3 and 7.

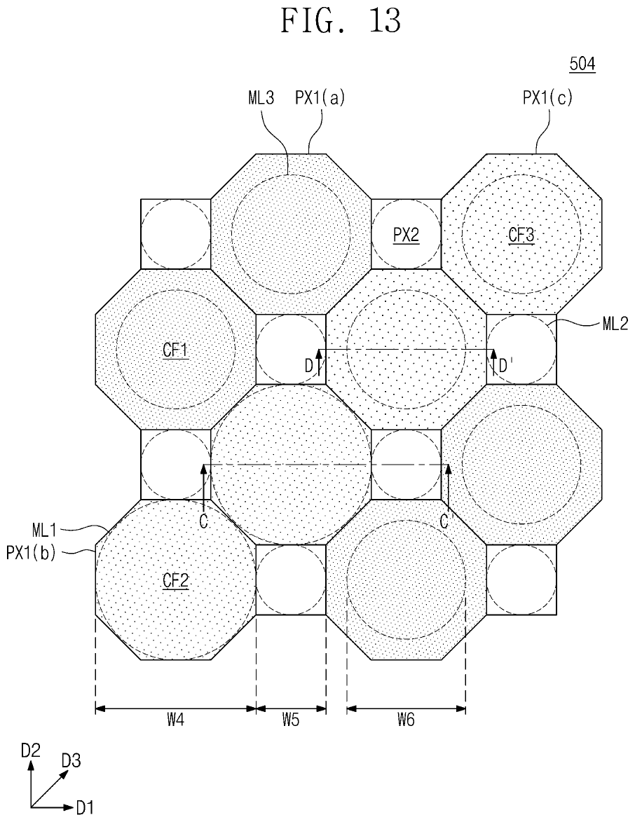

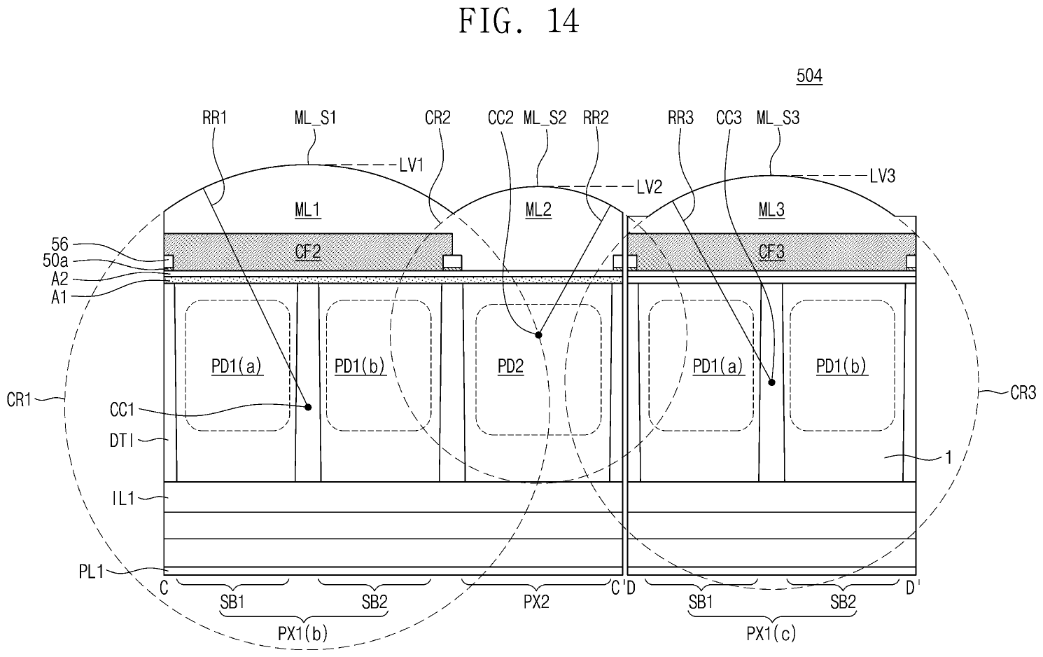

FIG. 13 is a plan view illustrating an image sensor according to some embodiments of the inventive concepts. FIG. 14 is a cross-sectional view taken along lines C-C′ and D-D′ of FIG. 13. For simplicity of illustration, FIG. 14 does not show some elements (e.g., the first and second sub-transfer gates TG1S1 and TG1S2 and the interconnection line 17) shown in FIG. 3.

Referring to FIGS. 13 and 14, in an image sensor 504 according to the present embodiments, a second color filter CF2 and a first micro lens ML1 may be disposed on the second color pixel PX1(b). A color filter may not exist on the second pixel PX2, and a second micro lens ML2 may be disposed on the second pixel PX2. A third color filter CF3 and a third micro lens ML3 may be disposed on the third color pixel PX1(c). In some embodiments, a color filter may not be provided between the first substrate 1 and the second micro lens ML2, and thus a space between the first substrate 1 and the second micro lens ML2 may be free of a color filter, as illustrated in FIG. 14.

A top surface ML_S1 of the first micro lens ML1 may have a first curvature, and a top surface ML_S2 of the second micro lens ML2 may have a second curvature. A top surface ML_S3 of the third micro lens ML3 may have a third curvature. The third curvature may be greater than the first curvature and may be less than the second curvature. A top end of the first micro lens ML1 may have a first level LV1. A top end of the second micro lens ML2 may have a second level LV2 lower than the first level LV1. A top end of the third micro lens ML3 may have a third level LV3 which is lower than the first level LV1 and is higher than the second level LV2. Stated differently, an uppermost end of the first micro lens ML1 may be farther than both an uppermost end of the second micro lens ML2 and an uppermost end of the third micro lens ML3 from the first substrate 1 (e.g., the back surface 1b of the first substrate 1), and the uppermost end of the third micro lens ML3 may be farther than the uppermost end of the second micro lens ML2 from the first substrate 1.

The top surface ML_S1 of the first micro lens ML1 may coincide with an arc of a first imaginary circle CR1 having a first radius RR1 and a first center CC1. The top surface ML_S2 of the second micro lens ML2 may coincide with an arc of a second imaginary circle CR2 having a second radius RR2 and a second center CC2. The top surface ML_S3 of the third micro lens ML3 may coincide with an arc of a third imaginary circle CR3 having a third radius RR3 and a third center CC3. The third radius RR3 may be less than the first radius RR1 and may be greater than the second radius RR2. The first center CC1 may be a focus of the first micro lens ML1. The first center CC1 may be located at a center of the second color pixel PX1(b) when viewed in a plan view. The second center CC2 may be a focus of the second micro lens ML2 and may be located at a center of the second pixel PX2 in a plan view. The third center CC3 may be a focus of the third micro lens ML3 and may be located at a center of the third color pixel PX1(c) in a plan view.

The first micro lens ML1 may have a fourth width W4 in the first direction D1. The second micro lens ML2 may have a fifth width W5 in the first direction D1. The third micro lens ML3 may have a sixth width W6 in the first direction D1. The sixth width W6 may be less than the fourth width W4 and may be greater than the fifth width W5.

In particular, the second color filter CF2 may have a blue color. Each of the first and third color filters CF1 and CF3 may have a red or green color. In the image sensor 504 according to the present embodiments, the first micro lens ML1 on the second color filter CF2 having the blue color may be formed to have the specific shape described above, and thus a reception rate of light having the blue color (i.e., blue light) may be increased. For example, in an image sensor installed in an under display camera (UDC), blue light having a relatively short wavelength may be easily absorbed in a display panel. Thus, a reception rate of the blue light may be reduced. However, the reception rate of the blue light may be increased in the image sensor 504 of the inventive concepts.

The color of the second color filter CF2 is not limited to the blue color. According to the inventive concepts, to increase a reception rate of light having a specific wavelength/color, a micro lens disposed on a corresponding pixel may be formed to have a shape different from that of another pixel adjacent thereto, as described above.

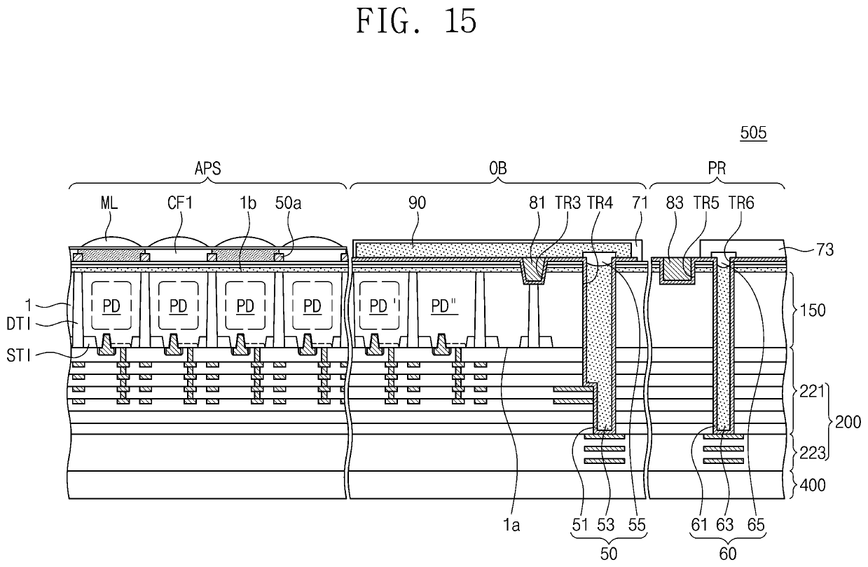

FIG. 15 is a cross-sectional view illustrating an image sensor according to some embodiments of the inventive concepts.

Referring to FIG. 15, an image sensor 505 according to the present embodiments may include a first substrate 1 having a pixel array region APS, an optical black region OB and a pad region PR, an interconnection layer 200 on a first surface 1a of the first substrate 1, and a base substrate 400 on the interconnection layer 200. The interconnection layer 200 may include an upper interconnection layer 221 and a lower interconnection layer 223. The pixel array region APS may include a plurality of pixels PX. The pixels PX disposed in the pixel array region APS may be substantially the same as described above with reference to FIGS. 1 to 14.

In the optical black region OB, a first connection structure 50, a first conductive pad 81 and a bulk color filter 90 may be provided on the first substrate 1. The first connection structure 50 may include a first light blocking pattern 51, an insulating pattern 53, and a first capping pattern 55.

The first light blocking pattern 51 may be provided on a second surface 1b of the first substrate 1. More particularly, the first light blocking pattern 51 may cover the second surface 1b and may conformally cover inner surfaces of a third trench TR3 and a fourth trench TR4. The first light blocking pattern 51 may penetrate a photoelectric conversion layer 150 and the upper interconnection layer 221 to connect the photoelectric conversion layer 150 to the interconnection layer 200. More particularly, the first light blocking pattern 51 may be in contact with interconnection lines in the upper interconnection layer 221 and the lower interconnection layer 223 and the isolation conductive pattern (e.g., the isolation conductive pattern 14 in FIG. 15) of the pixel separation portion DTI in the photoelectric conversion layer 150. Thus, the first connection structure 50 may be electrically connected to the interconnection lines in the interconnection layer 200. The first light blocking pattern 51 may include a metal material, for example, tungsten. The first light blocking pattern 51 may block light incident to the optical black region OB.

The first conductive pad 81 may be provided in the third trench TR3 to fill a remaining portion of the third trench TR3. The first conductive pad 81 may include a metal material, for example, aluminum. The first conductive pad 81 may be connected to the isolation conductive pattern 14 of FIG. 3. A negative bias voltage may be applied to the isolation conductive pattern 14 through the first conductive pad 81. Thus, a white spot and/or a dark current may be reduced or prevented.

The insulating pattern 53 may fill a remaining portion of the fourth trench TR4. The insulating pattern 53 may penetrate the photoelectric conversion layer 150 and may penetrate an entirety of or a portion of the interconnection layer 200. The first capping pattern 55 may be provided on a top surface of the insulating pattern 53. The first capping pattern 55 may cover the insulating pattern 53.

The bulk color filter 90 may be provided on the first conductive pad 81, the first light blocking pattern 51 and the first capping pattern 55. The bulk color filter 90 may cover the first conductive pad 81, the first light blocking pattern 51, and the first capping pattern 55. A first protective layer 71 may be provided on the bulk color filter 90 to seal or encapsulate the bulk color filter 90.

A photoelectric conversion region PD′ and a dummy region PD″ may be provided in the optical black region OB of the first substrate 1. For example, the photoelectric conversion region PD′ may be doped with dopants having the second conductivity type different from the first conductivity type. The second conductivity type may be, for example, an N-type. The pixel array region APS may include a plurality of photoelectric conversion regions PD. The photoelectric conversion region PD′ may have a similar structure to that of the photoelectric conversion region PD but may not perform the same operation (i.e., an operation of receiving light to generate an electrical signal) as the photoelectric conversion region PD. The dummy region PD″ may not be doped with dopants. A signal generated from the dummy region PD″ may be used as data for removing a process noise.

In the pad region PR, a second connection structure 60, a second conductive pad 83 and a second protective layer 73 may be provided on the first substrate 1. The second connection structure 60 may include a second light blocking pattern 61, an insulating pattern 63, and a second capping pattern 65.

The second light blocking pattern 61 may be provided on the second surface 1b of the first substrate 1. More particularly, the second light blocking pattern 61 may cover the second surface 1b and may conformally cover inner surfaces of a fifth trench TR5 and a sixth trench TR6. The second light blocking pattern 61 may penetrate the photoelectric conversion layer 150 and the upper interconnection layer 221 to connect the photoelectric conversion layer 150 to the interconnection layer 200. More particularly, the second light blocking pattern 61 may be in contact with the interconnection lines in the lower interconnection layer 223. Thus, the second connection structure 60 may be electrically connected to the interconnection lines in the interconnection layer 200. The second light blocking pattern 61 may include a metal material, for example, tungsten.

The second conductive pad 83 may be provided in the fifth trench TR5 to fill a remaining portion of the fifth trench TR5. The second conductive pad 83 may include a metal material, for example, aluminum. The second conductive pad 83 may function as an electrical connection path between the image sensor and an external device. The insulating pattern 63 may fill a remaining portion of the sixth trench TR6. The insulating pattern 63 may penetrate the photoelectric conversion layer 150 and may penetrate an entirety of or a portion of the interconnection layer 200. The second capping pattern 65 may be provided on the insulating pattern 63. The second protective layer 73 may cover a portion of the second light blocking pattern 61 and the second capping pattern 65.

A current applied through the second conductive pad 83 may flow to the isolation conductive pattern 14 of the pixel separation portion DTI through the second light blocking pattern 61, the interconnection lines in the interconnection layer 200, and the first light blocking pattern 51. Electrical signals generated from the photoelectric conversion regions PD and PD′ and the dummy region PD″ may be transmitted to an external device through the interconnection lines in the interconnection layer 200, the second light blocking pattern 61, and the second conductive pad 83.

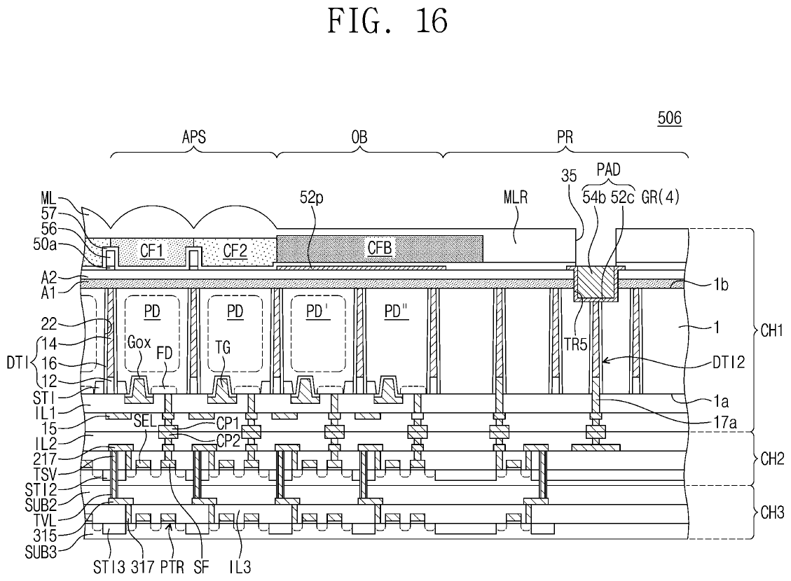

FIG. 16 is a cross-sectional view illustrating an image sensor according to some embodiments of the inventive concepts.

Referring to FIG. 16, an image sensor 506 according to the present embodiments may have a structure in which first to third sub-chips CH1 to CH3 are sequentially bonded to each other. For example, the first sub-chip CH1 may perform an image sensing function.

The first sub-chip CH1 may include transfer gates TG on a front surface 1a of a first substrate 1, and first interlayer insulating layers IL1 covering the transfer gates TG. A first device isolation portion STI may be disposed in the first substrate 1 to define active regions. The first sub-chip CH1 may further include internal connection contacts 17a. In the pad region PR, at least one of the internal connection contacts 17a may penetrate the filling insulation pattern 12 of the pixel separation portion DTI to connect at least one of first interconnection lines 15 to the isolation conductive pattern 14 of the pixel separation portion DTI and may be used to apply a negative bias voltage to the isolation conductive pattern 14. A protection layer 57 may cover the low-refractive index pattern 56, the light blocking grid 50a and the anti-reflection layer A2.

A lens residual layer MLR may include the same material as micro lenses ML. In the pad region PR, an opening 35 exposing a backside conductive pad PAD may be formed in the lens residual layer MLR.

The backside conductive pad PAD may be disposed in a fifth trench TR5. The backside conductive pad PAD may include a second conductive pattern 52c and a second metal pattern 54b. The second conductive pattern 52c may conformally cover a side surface and a bottom surface of the fifth trench TR5. The second conductive pattern 52c may have a single-layered or multi-layered structure including at least one of a titanium layer, a titanium nitride layer, or a tungsten layer. For example, the second metal pattern 54b may include aluminum. The second metal pattern 54b may fill the fifth trench TR5.

At least one of the internal connection contacts 17a may penetrate a filling insulation pattern 12 of a second pixel separation portion DTI2 under the backside conductive pad PAD to connect at least another of the first interconnection lines 15 to an isolation conductive pattern 14 of the second pixel separation portion DTI2. A first conductive pad CP1 may be disposed in a lowermost first interlayer insulating layer IL1. The first conductive pad CP1 may include copper. In the pad region PR, the lens residual layer MLR may be disposed on a second optical black pattern CFB.

The second sub-chip CH2 may include a second substrate SUB2, selection gates SEL, source follower gates SF and reset gates (not shown), which are disposed on the second substrate SUB2, and second interlayer insulating layers IL2 covering the gates. A second device isolation portion STI2 may be disposed in the second substrate SUB2 to define active regions. Second contacts and second interconnection lines 217 may be disposed in the second interlayer insulating layers IL2. A second conductive pad CP2 may be disposed in an uppermost second interlayer insulating layer IL2. The second conductive pad CP2 may include copper. The second conductive pad CP2 may be in contact with the first conductive pad CP1. The source follower gates SF may be connected to floating diffusion regions FD of the first sub-chip CH1, respectively.

The third sub-chip CH3 may include a third substrate SUB3, peripheral transistors PTR disposed on the third substrate SUB3, and third interlayer insulating layers IL3 covering the peripheral transistors PTR. A third device isolation portion STI3 may be disposed in the third substrate SUB3 to define active regions. Third contacts 317 and third interconnection lines 315 may be disposed in the third interlayer insulating layers IL3. An uppermost third interlayer insulating layer IL3 may be in contact with the second substrate SUB2. A through-electrode TSV may penetrate the second interlayer insulating layer IL2, the second device isolation portion STI2, the second substrate SUB2 and the third interlayer insulating layer IL3 to connect one of the second interconnection lines 217 to one of the third interconnection lines 315. A side surface of the through-electrode TSV may be surrounded by a via insulating layer TVL. The third sub-chip CH3 may include circuits for driving the first sub-chip CH1 and/or the second sub-chip CH2 and/or for storing electrical signals generated from the first sub-chip CH1 and/or the second sub-chip CH2.

The first pixels and the second pixels may have different sizes (e.g., widths) and different shapes in the image sensor of the inventive concepts, thereby realizing the highly integrated image sensor showing the clear image quality. In addition, the first pixel having a relatively great width may be divided into a plurality of sub-pixels to realize the auto-focus function.

In the image sensor of the inventive concepts, to increase the reception rate of light having a specific wavelength/color, the micro lens disposed on a corresponding pixel may be formed to have a shape different from that of the micro lens disposed on another pixel adjacent thereto. Thus, the image sensor capable of realizing the clear image quality may be provided.

In the image sensor of the inventive concepts, the transfer gate of the transfer transistor disposed in each of the sub-pixels may include a plurality of sub-transfer gates, and thus the transfer transistor may be operated as two transfer transistors connected in parallel to each other. Thus, the transfer transistor may be operated by a low driving voltage, and power consumption of the image sensor may be reduced.

Although terms (e.g., first, second or third) may be used herein to describe various elements, these elements should not be limited by these terms. These terms are only used to distinguish one element from another. For example, a first element may be referred to as a second element, and, similarly a second element may be referred to as a first element without departing from the teachings of the disclosure.

As used herein, an element or region that is “covering” or “surrounding” or “filling” another element or region may completely or partially cover or surround or fill the other element or region.

While some example embodiments of the inventive concepts have been particularly shown and described, it will be understood by one of ordinary skill in the art that variations in form and detail may be made therein without departing from the scope of the attached claims, The embodiments of FIGS. 1 through 16 may be combined with each other.

What is claimed is:

1. An image sensor comprising:
a substrate comprising a first surface and a second surface opposite to the first surface; and
a pixel separation portion in the substrate and separating first pixels and second pixels from each other,
wherein the first pixels and the second pixels are alternately arranged in a first direction and a second direction that intersects the first direction,
wherein each of the first pixels has a first width in the first direction,
wherein each of the second pixels has a second width in the first direction, and the second width is narrower than the first width, and
wherein the pixel separation portion comprises:
a main separation portion between the first and second pixels; and
protrusions, each of which protrudes from a side surface of the main separation portion in the first direction or the second direction,
wherein ones of the protrusions protrude into a respective one of the first pixels to divide the respective one of the first pixels into a plurality of sub-pixels.

2. The image sensor of claim 1, further comprising:
a first photoelectric conversion portion in the substrate in each of the sub-pixels;
a first floating diffusion region adjacent to the first surface of the substrate and in the substrate in each of the sub-pixels; and
a sub-transfer gate at a side of the first floating diffusion region in each of the sub-pixels.

3. The image sensor of claim 2, further comprising:
a first transistor on the first surface of the substrate and spaced apart from the sub-transfer gate and the first floating diffusion region in each of the sub-pixels.

4. The image sensor of claim 2, further comprising:
a second photoelectric conversion portion in the substrate in each of the second pixels;
a second floating diffusion region adjacent to the first surface of the substrate and in the substrate in each of the second pixels; and
a second transfer gate at a side of the second floating diffusion region in each of the second pixels.

5. The image sensor of claim 4, further comprising:
a second transistor on the first surface of the substrate and spaced apart from the second transfer gate and the second floating diffusion region in each of the second pixels.

6. The image sensor of claim 1, wherein each of the first pixels has an octagonal shape when viewed in a plan view, and
wherein each of the second pixels has a tetragonal shape when viewed in a plan view.

7. The image sensor of claim 1, further comprising:
a first micro lens on the second surface of the substrate and on a first one of the first pixels; and
a second micro lens on the second surface of the substrate and on one of the second pixels,
wherein an uppermost end of the first micro lens is farther than an uppermost end of the second micro lens from the second surface of the substrate.

8. The image sensor of claim 7, wherein the first micro lens has a first curvature, and
wherein the second micro lens has a second curvature greater than the first curvature.

9. The image sensor of claim 7, further comprising:
a first color filter between the second surface of the substrate and the first micro lens; and
a second color filter which is colorless and is between the second micro lens and the second surface of the substrate.

10. The image sensor of claim 9, wherein the first micro lens has a third width, and
wherein the second micro lens has a fourth width narrower than the third width.

11. The image sensor of claim 10, further comprising:
a third micro lens which is on the second surface of the substrate, is on a second one of the first pixels, and has a fifth width; and
a third color filter between the second surface of the substrate and the third micro lens,
wherein the fifth width is narrower than the third width and is wider than the fourth width,
wherein the first color filter has a blue color, and
wherein the third color filter has one of a green color and a red color.

12. An image sensor comprising:
a substrate comprising a first surface and a second surface opposite to the first surface;
a pixel separation portion in the substrate and separating first pixels and second pixels from each other, wherein the first pixels and the second pixels are alternately arranged in first and second directions intersecting each other, the pixel separation portion dividing each of the first pixels into a plurality of sub-pixels, and wherein each of the first pixels has a first width in the first direction, each of the second pixels has a second width in the first direction, and the second width is narrower than the first width;
a first photoelectric conversion portion in the substrate in each of the sub-pixels;
a first floating diffusion region adjacent to the first surface of the substrate and in the substrate in each of the sub-pixels;
a sub-transfer gate at a side of the first floating diffusion region in each of the sub-pixels;
a second photoelectric conversion portion in the substrate in each of the second pixels;
a second floating diffusion region adjacent to the first surface of the substrate and in the substrate in each of the second pixels; and
a second transfer gate at a side of the second floating diffusion region in each of the second pixels.

13. The image sensor of claim 12, wherein each of the first pixels has an octagonal shape when viewed in a plan view, and
wherein each of the second pixels has a tetragonal shape when viewed in a plan view.

14. The image sensor of claim 12, further comprising:
a first micro lens on the second surface of the substrate and on one of the first pixels; and
a second micro lens on the second surface of the substrate and on one of the second pixels,
wherein an uppermost end of the first micro lens is farther than an uppermost end of the second micro lens from the second surface of the substrate.

15. The image sensor of claim 14, wherein the first micro lens has a first curvature, and
wherein the second micro lens has a second curvature greater than the first curvature.

16. The image sensor of claim 14, further comprising:
a first color filter between the second surface of the substrate and the first micro lens,
wherein a space between the second micro lens and the second surface of the substrate is free of a color filter.

17. An image sensor comprising:
a substrate comprising a first surface and a second surface opposite to the first surface;
a pixel separation portion in the substrate and separating first pixels and second pixels from each other, wherein the first pixels and the second pixels are alternately arranged in first and second directions intersecting each other, and wherein each of the first pixels has a first width in the first direction, and each of the second pixels has a second width in the first direction, and the second width is narrower than the first width;
a first micro lens which is on the second surface of the substrate, is on a first one of the first pixels and has a third width;
a second micro lens which is on the second surface of the substrate, is on a second one of the first pixels and has a fourth width;
a third micro lens which is on the second surface of the substrate, is on one of the second pixels and has a fifth width;
a first color filter between the second surface of the substrate and the first micro lens; and
a second color filter between the second surface of the substrate and the second micro lens,
wherein a space between the third micro lens and the second surface of the substrate is free of a color filter,
wherein the fourth width is narrower than the third width and is wider than the fifth width,
wherein the first color filter has a blue color, and
wherein the second color filter has one of a green color and a red color.

18. The image sensor of claim 17, wherein an uppermost end of the first micro lens is farther than an uppermost end of the second micro lens from the second surface of the substrate, and
wherein an uppermost end of the third micro lens is closer than the uppermost end of the second micro lens to the second surface of the substrate.

19. The image sensor of claim 17, wherein the first micro lens has a first curvature,
wherein the second micro lens has a second curvature greater than the first curvature, and
wherein the third micro lens has a third curvature greater than the second curvature.

20. The image sensor of claim 17, wherein the pixel separation portion comprises portions, and ones of the portions extend into a respective one of the first pixels to divide the respective one of the first pixels into a plurality of sub-pixels, and
the image sensor further comprises:
a first photoelectric conversion portion in the substrate in each of the sub-pixels;
a first floating diffusion region adjacent to the first surface of the substrate and in the substrate in each of the sub-pixels; and
a sub-transfer gate at a side of the first floating diffusion region in each of the sub-pixels.
